(19) United States
(12) Patent Application Publication
(10) Pub. No.: US 2009/0206404 A1
(43) Pub. Date: Aug. 20, 2009

(54) REDUCING EXTERNAL RESISTANCE OF A MULTI-GATE DEVICE BY SILICIDATION

(76) Inventors: Ravi Pillarisetty, Portland, OR (US); Jack T. Kavalieros, Portland, OR (US); Titash Rakshit, Hillsboro, OR (US); Robert S. Chau, Beaverton, OR (US); Uday Shah, Portland, OR (US)

Correspondence Address: COOL PATENT, P.C.;c/o CPA Global, P.O. BOX 52050, MINNEAPOLIS, MN, 55402, US

(21) Appl. No.: 12/032,588

(22) Filed: Feb. 15, 2008

(51) Int. Cl. H01L 29/78; H01L 21/336

(52) U.S. Cl. 257/365; 257/412; 438/308; 438/283; 257/E29.264; 257/E21.438

(57) ABSTRACT

Reducing external resistance of a multi-gate device by silicidation is generally described. In one example, an apparatus includes a semiconductor substrate, a multi-gate fin coupled with the semiconductor substrate, the multi-gate fin having a first surface, a second surface, and a third surface, the multi-gate fin also having a gate region, a source region, and a drain region, the gate region being disposed between the source and drain regions wherein the source and drain regions of the multi-gate fin are fully or substantially silicized with a metal silicide, and a spacer dielectric material coupled to the first surface and the second surface wherein the spacer dielectric material substantially covers the first surface and the second surface in the source and drain regions.

### BACKGROUND

Generally, multi-gate devices or non-planar transistors such as tri-gate devices are emerging as a viable option to support future technology scaling. Reducing external resistance of a multi-gate device may at least improve drive current.

### BRIEF DESCRIPTION OF THE DRAWINGS

Embodiments disclosed herein are illustrated by way of example, and not by way of limitation, in the figures of the accompanying drawings in which like reference numerals refer to similar elements and in which:

FIG. 1 is a top-down schematic of a multi-gate fin, according to but one embodiment;

FIGS. 2a-2c are a side-view cross-section schematic of reducing external resistance (Rₑₓₜ) of a multi-gate device by silicidation, according to but one embodiment;

FIG. 3 is a flow diagram of a method for reducing external resistance of a multi-gate device by silicidation, according to but one embodiment; and

FIG. 4 is a diagram of an example system in which embodiments of the present invention may be used, according to but one embodiment.

It will be appreciated that for simplicity and/or clarity of illustration, elements illustrated in the figures have not necessarily been drawn to scale. For example, the dimensions of some of the elements may be exaggerated relative to other elements for clarity. Further, if considered appropriate, reference numerals have been repeated among the figures to indicate corresponding and/or analogous elements.

### DETAILED DESCRIPTION

Embodiments of reducing external resistance of a multi-gate device by silicidation are described herein. In the following description, numerous specific details are set forth to provide a thorough understanding of embodiments disclosed herein. One skilled in the relevant art will recognize, however, that the embodiments disclosed herein can be practiced without one or more of the specific details, or with other methods, components, materials, and so forth. In other instances, well-known structures, materials, or operations are not shown or described in detail to avoid obscuring aspects of the specification.

Reference throughout this specification to “one embodiment” or “an embodiment” means that a particular feature, structure or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

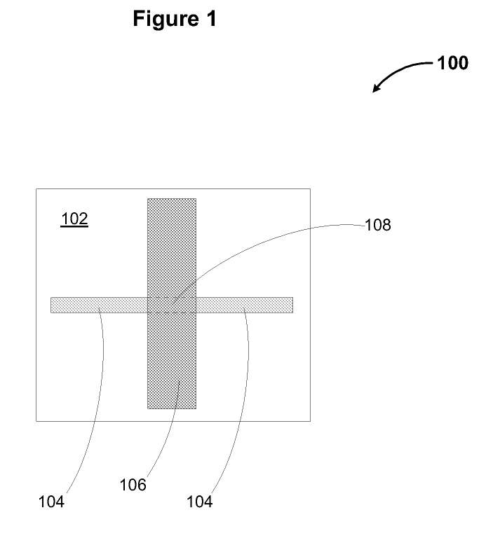

FIG. 1 is a top-down schematic of a multi-gate fin, according to but one embodiment. In an embodiment, an apparatus 100 includes a dielectric material 102 such as shallow-trench isolation (STI) material 102, multi-gate fin 104, and gate electrode material 106, each coupled as shown.

Multi-gate transistors or non-planar transistors 100, such as tri-gate devices, may emerge as an option to support future technology scaling of transistor devices. However, drive current in multi-gate devices may be severely hindered by parasitic resistance. The parasitic resistance may result from difficulty in forming low interfacial resistance between epitaxial growth (epi) and fin 104 surfaces (i.e.—sidewalls). For example, sidewall spacer dielectric may block epi growth along the sidewall surfaces of the fin 104. This may result in forming a low resistance contact only on a portion of the fin 104 that is not impeded by the spacer dielectric, for example. Such effect may bottleneck the flow of current into the fin 104, resulting in a degradation of external resistance (Rₑₓₜ) of the multi-gate transistor.

In an embodiment, a multi-gate fin 104 includes a gate region 108 underlying the gate electrode 106 and source/drain regions 104 (i.e.—the visible portions labeled with tags 104), the gate region 108 being disposed between the source and drain regions 104. The source and drain regions 104 include completely or nearly completely silicized material, according to an embodiment. In another embodiment, the silicized material includes metal silicide such as silicide comprising nickel, for example.

Embodiments disclosed herein include at least a structure and a process to silicidize the fin 104 in the source/drain regions of a multi-gate fin using an electrically conductive material such as metal. The relatively higher conductivity of the silicized fin compared to the fin comprising only semiconductor material may significantly alleviate the Rₑₓₜ degradation corresponding with an improvement in drive current for a multi-gate device incorporating the silicized fin.

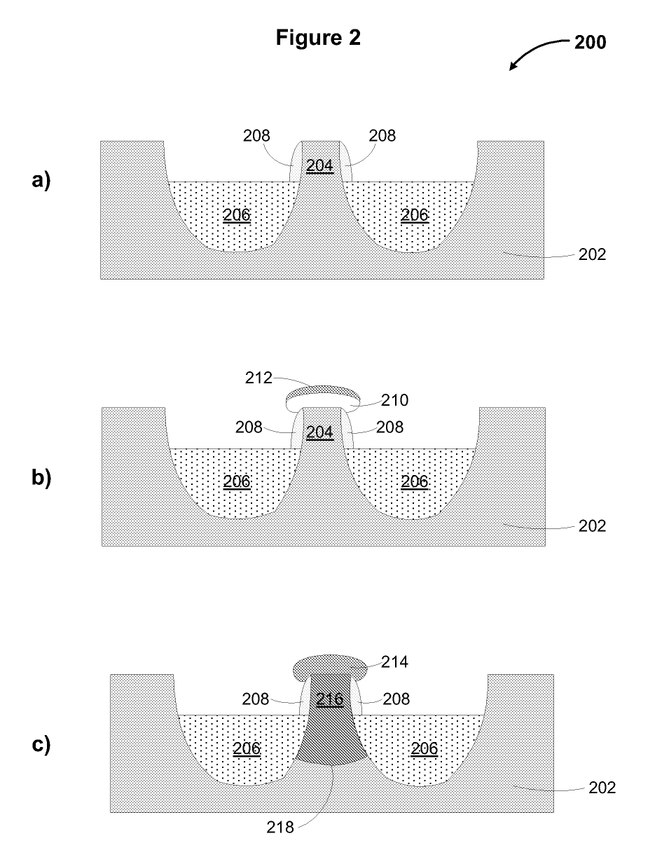

FIGS. 2a-2c are a side-view cross-section schematic of reducing external resistance (Rₑₓₜ) of a multi-gate device by silicidation. Apparatus 200 may include cross-section depictions through the source or drain region of a multi-gate fin 204, 216. In an embodiment according to FIG. 2a, an apparatus 200 includes a semiconductor substrate 202, multi-gate fin 204, shallow trench isolation (STI) material 206, and spacer dielectric 208, each coupled as shown. In an embodiment, the multi-gate fin 204 includes a semiconductor material such as silicon, for example. Multi-gate fin 204 may include any other material amenable to silicidation in other embodiments.

Multi-gate fin 204 may include a first surface, a second surface, and a third surface, the first and second surfaces being coupled to spacer dielectric 208. The third surface may be exposed so that it can be coupled with epitaxial growth 210 in FIG. 2b. In an embodiment, the first and second surfaces refer to the sidewalls of multi-gate fin 204 and the third surface refers to the top portion of multi-gate fin 204.

In an embodiment, spacer dielectric 208 is formed on the first and second surfaces of multi-gate fin 204. Spacer dielectric 208 may facilitate full silicidation (FUSI) of the multi-gate fin in the source/drain regions by providing spacer confinement 208 of the FUSI process depicted in FIGS. 2b-2c. In an embodiment, spacer dielectric 208 deposition, associated etching, and other process steps to form spacer dielectric 208 are selected to ensure adequate coverage of the first and second surfaces of multi-gate fin 204. In one embodiment, the spacer dielectric 208 is not recessed by etching.

Various types of amorphization implantation may be used to control the depth of silicide penetration into the fin 204 in subsequent processing. In an embodiment, implantation is used prior to metal 212 deposition and silicidation anneal 216 to control the depth of silicidation in fin 204.

In an embodiment according to FIG. 2b, an apparatus 200 includes a semiconductor substrate 202, multi-gate fin 204, STI material 206, spacer dielectric 208, epitaxial growth 210, and metal 212, each coupled as shown. FIG. 2b may be a depiction of FIG. 2a after epitaxial growth 210 has been deposited to the third surface of multi-gate fin 204 and metal 212 has been deposited to the epitaxial growth (epi) 210. In an embodiment, epitaxial growth 210 includes epitaxially grown silicon. Metal 212 may include nickel, for example, or any other metal that silicidizes multi-gate fin 204 upon annealing. In an embodiment, spacer dielectric 208 is disposed to prevent epitaxial growth 210 from being coupled to the first surface and the second surface of multi-gate fin 204. Spacer dielectric 208 may provide spacer confinement to enhance silicidation of multi-gate fin 204.

In an embodiment according to FIG. 2c, an apparatus 200 includes a semiconductor substrate 202, STI material 206, spacer dielectric 208, silicized epitaxial growth 214, and silicized multi-gate fin 216, each coupled as shown. FIG. 2c may depict an apparatus 200 according to FIG. 2b after a silicidation process silicidizes the epitaxial growth 214 and the multi-gate fin 216. A silicidation process may include a thermal process such as annealing. In an embodiment, the metal 212 thickness and anneal time is selected to substantially or fully silicidize multi-gate fin 216. Silicidation of multi-gate fin 216 may significantly increase fin 216 conductivity to alleviate Rₑₓₜ degradation caused by current bottlenecking.

In an embodiment, an apparatus 200 includes a semiconductor substrate 202, a multi-gate fin 216 coupled with the semiconductor substrate, the multi-gate fin 216 including a first surface, a second surface, and a third surface. The multi-gate fin 216 may be a tri-gate fin where the first and second surfaces are substantially parallel to one another and where the third surface forms a plane that is substantially perpendicular to the first and second surfaces.

The multi-gate fin 216 may include a gate region, a source region, and a drain region, the gate region being disposed between the source and drain regions. In an embodiment, the source and drain regions of the multi-gate fin 216 are fully or substantially silicized with a metal silicide. The metal silicide of the multi-gate fin may reduce Rₑₓₜ of a multi-gate device that incorporates the multi-gate fin. In an embodiment, the metal 212 includes nickel or any other suitable metal for silicidation that increases fin 216 conductivity.

A spacer dielectric material 208 may be coupled to the first surface and the second surface of the multi-gate fin 216. In an embodiment, the spacer dielectric material 208 substantially covers the first and the second surfaces in the source and drain regions of a multi-gate fin 216. In another embodiment, the spacer dielectric material 208 is disposed to prevent epitaxial growth 214 from being coupled to the first surface and the second surface.

Epitaxial growth 214 may be coupled to a third surface of a multi-gate fin 216 in the source and drain region. In an embodiment, the epitaxial growth 214 includes metal silicide. Silicized epitaxial growth 214 may reduce Rₑₓₜ of a multi-gate device incorporating the silicized epitaxial growth 214. In an embodiment, the metal 212 includes nickel or any other suitable metal for silicidation that increases fin 216 conductivity.

Silicidation of the multi-gate fin 216 may plow a dopant in fin 216 towards an interface 218 between the silicized multi-gate fin 216 and the semiconductor substrate 202. In an embodiment, the multi-gate fin 216 includes an aggregation of a dopant at an interface 218 between the metal silicide of the multi-gate fin 216 and the semiconductor substrate 202. The dopant may be any suitable n-type or p-type dopant including phosphorous, arsenic, or boron, for example. The dopant may have been implanted in prior process steps. In an embodiment, the aggregation of a dopant at the interface 218 lowers the Schottky barrier at the interface 218 reducing Rₑₓₜ and/or preventing junction leakage associated with a metal-to-well junction.

The semiconductor substrate 202 may be a bulk substrate as depicted in FIG. 2 or silicon-on-insulator (SOI) substrate, or any other suitable semiconductor substrate. The semiconductor substrate may comprise silicon, any suitable semiconductor material, or combinations thereof. In an embodiment, a bulk substrate 202 is selected to allow deeper silicidation of the multi-gate fin 216 in the source and drain regions. Deeper silicidation may provide a larger silicided volume in the multi-gate fin 216 resulting in a greater reduction in Rₑₓₜ. In an embodiment, a bulk substrate 202 allows deeper silicidation of the multi-gate fin 216 than an SOI substrate, for example.

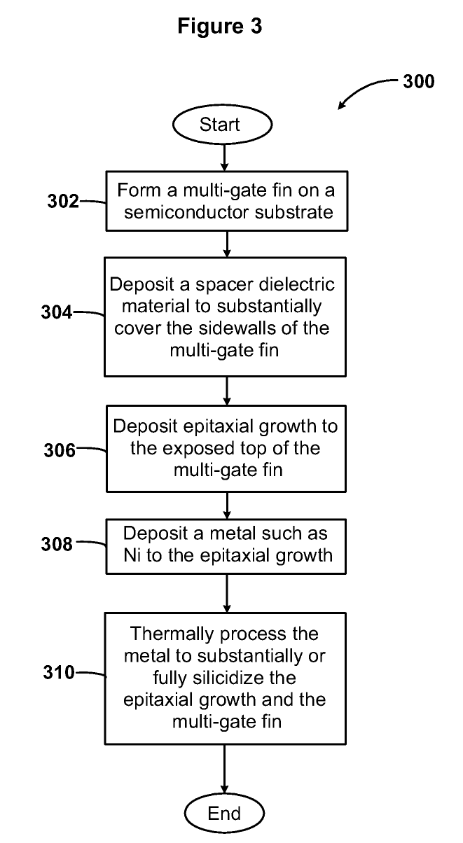

FIG. 3 is a flow diagram of a method for reducing external resistance of a multi-gate device by silicidation, according to but one embodiment. In an embodiment, a method 300 includes forming a multi-gate fin on a semiconductor substrate at box 302, depositing a spacer dielectric material to substantially cover the sidewalls of the multi-gate fin at box 304, depositing epitaxial growth to the exposed top of the multi-gate fin at box 306, depositing a metal such as nickel to the epitaxial growth at box 308, and thermally processing the metal to substantially or fully silicidize the epitaxial growth and the multi-gate fin at box 310.

In an embodiment, a method 300 includes forming at least one multi-gate fin on a semiconductor substrate 302, the multi-gate fin include a first surface, a second surface, and a third surface. The first and second surfaces may be substantially parallel to each other and the third surface may form a plane that is substantially perpendicular to the first and second surfaces according to one embodiment. The multi-gate fin may further including a gate region, a source region, and a drain region, the gate region being disposed between the source and drain regions.

A method 300 may further include depositing or forming a spacer dielectric material to substantially cover the first surface and the second surface in the source and drain regions of the multi-gate fin 304, depositing epitaxial growth to the third surface in the source and drain regions of the multi-gate fin 306, depositing a metal to the epitaxial growth 308, and thermally processing the metal to at least substantially silicidize the epitaxial growth and the multi-gate fin 310.

Forming at least one multi-gate fin on a semiconductor substrate 302 may include forming at least one multi-gate fin on a bulk semiconductor substrate where the bulk semiconductor substrate allows deeper silicidation of the multi-gate fin in the source and drain regions than a silicon-on-insulator (SOI) substrate. Deeper silicidation may further reduce Rₑₓₜ of a multi-gate device incorporating the bulk substrate. In another embodiment, forming at least one multi-gate fin 302 includes forming at least one tri-gate fin.

Various types of amorphization implantation may be used to control the depth of silicide penetration into the fin. In an embodiment, implantation is used prior to metal deposition 308 and silicidation anneal 310 to control the depth of silicidation in fin.

Depositing a spacer dielectric material 304 may prevent the deposition of epitaxial growth on the first surface and the second surface of a multi-gate fin. Spacer deposition 304 may allow a spacer-confined fully silicided (FUSI) process to substantially silicidize the multi-gate fin. Depositing epitaxial growth to the third surface in the source and drain regions of the multi-gate fin 306 may include epitaxially growing silicon on the third surface. In an embodiment, the third surface includes silicon. Depositing a metal to the epitaxial growth 308 may include depositing nickel, any other suitable metal, or combinations thereof, to the epitaxial growth. In an embodiment, a metal includes alloys or combinations of metallic materials.

Thermally processing the metal to substantially or fully silicidize the epitaxial growth and the multi-gate fin 310 may lower the Schottky barrier of the multi-gate fin reducing the Rₑₓₜ of a multi-gate device that incorporates the multi-gate fin. In an embodiment, thermally processing the metal 310 includes annealing the metal where annealing the metal substantially or fully silicidizes the epitaxial growth and substantially or fully silicidizes the multi-gate fin. Substantially silicidizing includes fully or nearly fully silicidizing according to one embodiment. Annealing the metal 310 may plow a dopant in the multi-gate fin towards the semiconductor substrate. In an embodiment, thermally processing the metal 310 plows a dopant comprising phosphorous in the multi-gate fin towards the semiconductor substrate, the phosphorous aggregating at an interface between the silicidized multi-gate fin and the semiconductor substrate to reduce Rₑₓₜ in a multi-gate device, reduce junction leakage in a multi-gate device, or combinations thereof. Embodiments already disclosed with respect to FIGS. 1 and 2 may be incorporated in method 300.

Various operations may be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

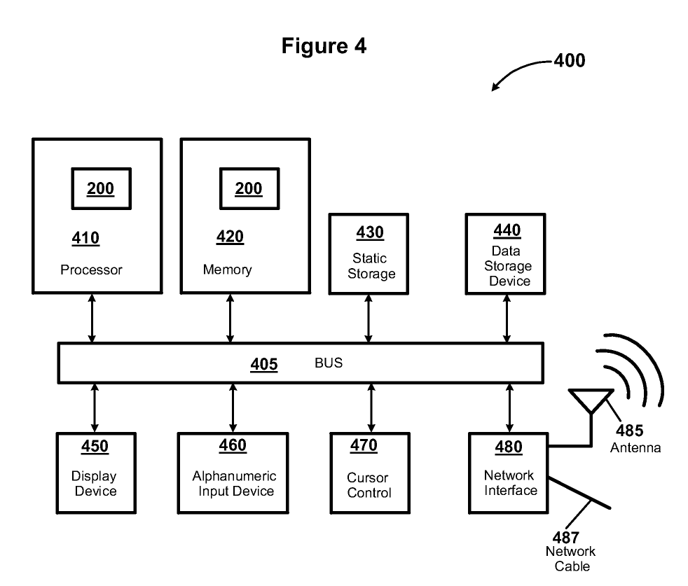

FIG. 4 is a diagram of an example system in which embodiments of the present invention may be used, according to but one embodiment. System 400 is intended to represent a range of electronic systems (either wired or wireless) including, for example, desktop computer systems, laptop computer systems, personal computers (PC), wireless telephones, personal digital assistants (PDA) including cellular-enabled PDAs, set top boxes, pocket PCs, tablet PCs, DVD players, or servers, but is not limited to these examples and may include other electronic systems. Alternative electronic systems may include more, fewer and/or different components.

In one embodiment, electronic system 400 includes an apparatus 200 having a silicized multi-gate fin in accordance with embodiments described with respect to FIGS. 1-2. In an embodiment, an apparatus 200 having a silicized multi-gate fin as described herein is part of an electronic system's processor 410 or memory 420.

Electronic system 400 may include bus 405 or other communication device to communicate information, and processor 410 coupled to bus 405 that may process information. While electronic system 400 may be illustrated with a single processor, system 400 may include multiple processors and/or co-processors. In an embodiment, processor 410 includes an apparatus 200 having a silicized multi-gate fin in accordance with embodiments described herein. System 400 may also include random access memory (RAM) or other storage device 420 (may be referred to as memory), coupled to bus 405 and may store information and instructions that may be executed by processor 410.

Memory 420 may also be used to store temporary variables or other intermediate information during execution of instructions by processor 410. Memory 420 is a flash memory device in one embodiment. In another embodiment, memory 420 includes an apparatus 200 having a silicized multi-gate fin as described herein.

System 400 may also include read only memory (ROM) and/or other static storage device 430 coupled to bus 405 that may store static information and instructions for processor 410. Data storage device 440 may be coupled to bus 405 to store information and instructions. Data storage device 440 such as a magnetic disk or optical disc and corresponding drive may be coupled with electronic system 400.

Electronic system 400 may also be coupled via bus 405 to display device 450, such as a cathode ray tube (CRT) or liquid crystal display (LCD), to display information to a user. Alphanumeric input device 460, including alphanumeric and other keys, may be coupled to bus 405 to communicate information and command selections to processor 410. Another type of user input device is cursor control 470, such as a mouse, a trackball, or cursor direction keys to communicate information and command selections to processor 410 and to control cursor movement on display 450.

Electronic system 400 further may include one or more network interfaces 480 to provide access to network, such as a local area network. Network interface 480 may include, for example, a wireless network interface having antenna 485, which may represent one or more antennae. Network interface 480 may also include, for example, a wired network interface to communicate with remote devices via network cable 487, which may be, for example, an Ethernet cable, a coaxial cable, a fiber optic cable, a serial cable, or a parallel cable.

In one embodiment, network interface 480 may provide access to a local area network, for example, by conforming to an Institute of Electrical and Electronics Engineers (IEEE) standard such as IEEE 802.11b and/or IEEE 802.11g standards, and/or the wireless network interface may provide access to a personal area network, for example, by conforming to Bluetooth standards. Other wireless network interfaces and/or protocols can also be supported.

IEEE 802.11b corresponds to IEEE Std. 802.11b-1999 entitled “Local and Metropolitan Area Networks, Part 11: Wireless LAN Medium Access Control (MAC) and Physical Layer (PHY) Specifications: Higher-Speed Physical Layer Extension in the 2.4 GHz Band,” approved Sep. 16, 1999 as well as related documents. IEEE 802.11g corresponds to IEEE Std. 802.11g-2003 entitled “Local and Metropolitan Area Networks, Part 11: Wireless LAN Medium Access Control (MAC) and Physical Layer (PHY) Specifications, Amendment 4: Further Higher Rate Extension in the 2.4 GHz Band,” approved Jun. 27, 2003 as well as related documents. Bluetooth protocols are described in “Specification of the Bluetooth System: Core, Version 1.1,” published Feb. 22, 2001 by the Bluetooth Special Interest Group, Inc. Previous or subsequent versions of the Bluetooth standard may also be supported.

In addition to, or instead of, communication via wireless LAN standards, network interface(s) 480 may provide wireless communications using, for example, Time Division, Multiple Access (TDMA) protocols, Global System for Mobile Communications (GSM) protocols, Code Division, Multiple Access (CDMA) protocols, and/or any other type of wireless communications protocol.

In an embodiment, a system 400 includes one or more omnidirectional antennae 485, which may refer to an antenna that is at least partially omnidirectional and/or substantially omnidirectional, and a processor 410 coupled to communicate via the antennae.

The above description of illustrated embodiments, including what is described in the Abstract, is not intended to be exhaustive or to limit to the precise forms disclosed. While specific embodiments and examples are described herein for illustrative purposes, various equivalent modifications are possible within the scope of this description, as those skilled in the relevant art will recognize.

These modifications can be made in light of the above detailed description. The terms used in the following claims should not be construed to limit the scope to the specific embodiments disclosed in the specification and the claims. Rather, the scope of the embodiments disclosed herein is to be determined entirely by the following claims, which are to be construed in accordance with established doctrines of claim interpretation.

What is claimed is:

1. An apparatus comprising:
a semiconductor substrate;
a multi-gate fin coupled with the semiconductor substrate, the multi-gate fin comprising a first surface, a second surface, and a third surface, the multi-gate fin further comprising a gate region, a source region, and a drain region, the gate region being disposed between the source and drain regions wherein the source and drain regions of the multi-gate fin are fully or substantially silicized with a metal silicide; and
a spacer dielectric material coupled to the first surface and the second surface wherein the spacer dielectric material substantially covers the first surface and the second surface in the source and drain regions.

2. An apparatus according to claim 1 further comprising:
epitaxial growth coupled to the third surface of the multi-gate fin in the source and drain regions wherein the epitaxial growth comprises metal silicide, the spacer dielectric material being disposed to prevent epitaxial growth from being coupled to the first surface and the second surface, wherein the metal silicide of the multi-gate fin and the metal silicide of the epitaxial growth reduces external resistance (Rₑₓₜ) of a multi-gate device incorporating the multi-gate fin.

3. An apparatus according to claim 2 wherein the metal silicide of the epitaxial growth comprises nickel and wherein the metal silicide of the multi-gate fin comprises nickel.

4. An apparatus according to claim 1 wherein the multi-gate fin comprises an aggregation of a dopant at an interface between the metal silicide of the multi-gate fin and the semiconductor substrate.

5. An apparatus according to claim 4 wherein the dopant is phosphorous and wherein the aggregation of phosphorous reduces external resistance (Rₑₓₜ) of a multi-gate device incorporating the multi-gate fin.

6. An apparatus according to claim 1 wherein the semiconductor substrate is a bulk substrate comprising silicon, the bulk substrate being selected to allow deeper silicidation of the multi-gate fin in the source and drain regions than a silicon-on-insulator (SOI) substrate.

7. An apparatus according to claim 1 wherein the multi-gate fin is a tri-gate fin and wherein the first and second surfaces are substantially parallel to each other and wherein the third surface is substantially perpendicular to the first and second surfaces.

8. A method comprising:
forming at least one multi-gate fin on a semiconductor substrate, the multi-gate fin comprising a first surface, a second surface, and a third surface, the multi-gate fin further comprising a gate region, a source region, and a drain region, the gate region being disposed between the source and drain regions;
depositing a spacer dielectric material to substantially cover the first surface and the second surface in the source and drain regions;
depositing epitaxial growth to the third surface in the source and drain regions;
depositing a metal to the epitaxial growth; and
thermally processing the metal to at least substantially silicidize the epitaxial growth and the multi-gate fin.

9. A method according to claim 8 wherein forming at least one multi-gate fin on a semiconductor substrate comprises forming at least one tri-gate fin on a bulk semiconductor substrate, wherein the bulk semiconductor substrate allows deeper silicidation of the tri-gate fin in the source and drain regions than a silicon-on-insulator (SOI) substrate.

10. A method according to claim 8 wherein depositing a spacer dielectric material prevents the deposition of epitaxial growth on the first surface and the second surface to allow a spacer-confined fully silicided (FUSI) process to substantially silicidize the multi-gate fin.

11. A method according to claim 8 wherein depositing epitaxial growth to the third surface in the source and drain regions comprises epitaxially growing silicon on the third surface wherein the third surface comprises silicon.

12. A method according to claim 8 wherein depositing a metal to the epitaxial growth comprises depositing nickel to the epitaxial growth, the method further comprising:
implanting the multi-gate fin prior to depositing a metal to control the depth of silicidation in the multi-gate fin.

13. A method according to claim 8 wherein thermally processing the metal to at least substantially silicidize the epitaxial growth and the multi-gate fin lowers the Schottky barrier of the multi-gate fin and reduces the external resistance (Rₑₓₜ) of a multi-gate device that incorporates the multi-gate fin.

14. A method according to claim 8 wherein thermally processing the metal comprises annealing the metal wherein annealing the metal substantially silicidizes the epitaxial growth and substantially silicidizes the multi-gate fin and wherein annealing the metal plows a dopant in the multi-gate fin towards the semiconductor substrate.

15. A method according to claim 8 wherein thermally processing the metal plows a dopant comprising phosphorous in the multi-gate fin towards the semiconductor substrate, the phosphorous aggregating at an interface between the silicidized multi-gate fin and the semiconductor substrate to reduce external resistance (Rₑₓₜ) in a multi-gate device or to reduce junction leakage in a multi-gate device, or combinations thereof.
